(19) United States
(12) Patent Application Publication
(10) Pub. No.: US 2025/0098390 A1
(43) Pub. Date: Mar. 20, 2025

(54) PANEL FOR ELECTRONIC DEVICE AND ELECTRONIC DEVICE

(71) Applicant: SAMSUNG ELECTRONICS CO., LTD., Suwon-si (KR)

(72) Inventors: Joonseok KIM, Suwon-si (KR); Joonyun KIM, Suwon-si (KR); Huije RYU, Suwon-si (KR); Chang Seok LEE, Suwon-si (KR); Luhing HU, Suwon-si (KR)

(21) Appl. No.: 18/653,130

(22) Filed: May 2, 2024

(30) Foreign Application Priority Data
Sep. 18, 2023 (KR) 10-2023-0124282

(51) Int. Cl. H01L 27/15; H01L 25/075; H01L 25/16; H01L 27/12; H01L 33/62

(52) U.S. Cl. CPC H10H 29/142; H01L 25/0753; H01L 25/167; H10D 86/481; H10D 86/60; H10H 20/857

(57) ABSTRACT

A panel includes: a substrate, unit pixels arranged repeatedly on the substrate, and unit pixel circuits including a unit pixel circuit repeatedly arranged on the substrate and electrically connected to a unit pixel. Each unit pixel includes a red sub-pixel including a red optoelectronic element configured to display red color or detect red light, a green sub-pixel including a green optoelectronic element configured to display green color or detect green light, and a blue sub-pixel including a blue optoelectronic element configured to display blue color or detect blue light. Each unit pixel circuit includes a red pixel circuit electrically connected to the red optoelectronic element, a green pixel circuit electrically connected to the green optoelectronic element, and a blue pixel circuit electrically connected to the blue optoelectronic element. The red pixel circuit, the green pixel circuit, and the blue pixel circuit are stacked along a thickness direction of the substrate.

### CROSS-REFERENCE TO RELATED APPLICATION

This application claims priority to Korean Patent Application No. 10-2023-0124282, filed on Sep. 18, 2023, and all the benefits accruing therefrom under 35 U.S.C. § 119, the content of which in its entirety is herein incorporated by reference.

### BACKGROUND

### (a) Field of the Disclosure

The present disclosure relates to a panel for an electronic device and an electronic device.

### (b) Description of the Related Art

A panel for electronic devices, such as a display panel or a sensor array panel, includes a pixel array consisting of a plurality of pixels (sub-pixels), and each pixel (sub-pixel) of the pixel array may be independently controlled and/or driven by a pixel circuit individually connected.

### SUMMARY

In order to implement high performance panels such as high-resolution display panels or high-sensitivity sensor array panels, it is required to increase the number of the pixels per a unit area, and accordingly, it is necessary to reduce the size of each pixel. However, when reducing the size of each pixel, the area of each pixel circuit positioned corresponding to each pixel must also be reduced, so the stability and performance of the driving may be deteriorated.

Some example embodiments provide a panel for an electronic device capable of preventing a deterioration of the stability and performance of the pixel circuit, even if the pixel size is reduced.

Some example embodiments provide an electronic device including the panel for the electronic device.

A panel for an electronic device according to some example embodiments includes: a substrate, a plurality of unit pixels arranged repeatedly along a direction parallel to a major surface of the substrate, and a plurality of unit pixel circuits including a unit pixel circuit that is repeatedly arranged along the direction parallel to the major surface of the substrate and electrically connected to a corresponding unit pixel among the plurality of unit pixels, where each unit pixel includes: a red sub-pixel including a red optoelectronic element configured to display red color or detect light in a red wavelength spectrum, a green sub-pixel including a green optoelectronic element configured to display green color or detect light in a green wavelength spectrum, and a blue sub-pixel including a blue optoelectronic element configured to display blue color or detect light in a blue wavelength spectrum, each unit pixel circuit includes: a red pixel circuit electrically connected to the red optoelectronic element, green pixel circuit electrically connected to the green optoelectronic element, and a blue pixel circuit electrically connected to the blue optoelectronic element, and the red pixel circuit, the green pixel circuit, and the blue pixel circuit are stacked each other along a thickness direction of the substrate.

The red optoelectronic element, the green optoelectronic element, and the blue optoelectronic element may be arranged side by side along the direction parallel to the major surface of the substrate, the red pixel circuit may overlap with the red optoelectronic element along the thickness direction of the substrate and additionally overlap with at least one of the green optoelectronic element or the blue optoelectronic element, the green pixel circuit may overlap with the green optoelectronic element along the thickness direction of the substrate and additionally overlap with at least one of the red optoelectronic element or the blue optoelectronic element, and the blue pixel circuit may overlap with the blue optoelectronic element along the thickness direction of the substrate and additionally overlap with at least one of the red optoelectronic element or the green optoelectronic element.

The red pixel circuit may overlap about 50% to about 100% of a total area of the red optoelectronic element, the green optoelectronic element, and the blue optoelectronic element, the green pixel circuit may overlap about 50% to about 100% of the total area of the red optoelectronic element, the green optoelectronic element, and the blue optoelectronic element, and the blue pixel circuit may overlap about 50% to about 100% of the total area of the red optoelectronic element, the green optoelectronic element, and the blue optoelectronic element.

Each active layer of the red pixel circuit, the green pixel circuit, and the blue pixel circuit may include a two-dimensional material, oxide, silicon, an organic material, or a combination thereof.

Each active layer of the red pixel circuit, the green pixel circuit, and the blue pixel circuit may include a monocrystalline or a monocrystalline-like two-dimensional material configured to be grown or deposited at temperatures from about 25° C. to about 400° C.

The two-dimensional material may include a two-dimensional inorganic compound, graphene, borophene, germanene, stanene, phosphorene, bismuthene, tellurene, metal chalcogenide, boron nitride, black phosphorus, a two-dimensional organic compound, a two-dimensional organic/inorganic compound, or combinations thereof.

Each active layer of the red pixel circuit, the green pixel circuit, and the blue pixel circuit may include 1 to 10 monolayers made of the two-dimensional material.

Each thickness of the red pixel circuit, the green pixel circuit, and the blue pixel circuit may be about 0.1 nanometers (nm) to about 3 micrometers (μm).

The red pixel circuit, the green pixel circuit, and the blue pixel circuit may be separated by an insulation layer, and each of the red pixel circuit, the green pixel circuit, and the blue pixel circuit may be electrically connected to corresponding one of the red optoelectronic element, the green optoelectronic element, the blue optoelectronic element through a conductive material filled in a via-hole in the insulation layer.

The plurality of unit pixel circuits may include a first unit pixel circuit and a second unit pixel circuit adjacent to each other in the thickness direction of the substrate, and the red pixel circuit, the green pixel circuit, and the blue pixel circuit included in the first unit pixel circuit, and the red pixel circuit, the green pixel circuit, and the blue pixel circuit included in the second unit pixel circuit may be stacked each other along the thickness direction of the substrate.

The plurality of unit pixels may include a first unit pixel and a second unit pixel adjacent to each other, the red optoelectronic element, the green optoelectronic element, and the blue optoelectronic element included the first unit pixel, and the red optoelectronic element, the green optoelectronic element, and the blue optoelectronic element included in the second unit pixel may be arranged side by side along the direction parallel to the major surface of the substrate, the red pixel circuit of the first unit pixel circuit may overlap with about 50% to about 100% of a total area of the red optoelectronic element, the green optoelectronic element, and the blue optoelectronic element included the first unit pixel, and the red optoelectronic element, the green optoelectronic element, and the blue optoelectronic element included in the second unit pixel, the green pixel circuit of the first unit pixel circuit may overlap with about 50% to about 100% of the total area of the red optoelectronic element, the green optoelectronic element, and the blue optoelectronic element included the first unit pixel, and the red optoelectronic element, the green optoelectronic element, and the blue optoelectronic element included in the second unit pixel, and the blue pixel circuit of the first unit pixel circuit may overlap with about 50% to about 100% of the total area of the red optoelectronic element, the green optoelectronic element, and the blue optoelectronic element included the first unit pixel, and the red optoelectronic element, the green optoelectronic element, and the blue optoelectronic element included in the second unit pixel.

Each of the red optoelectronic element, the green optoelectronic element, the blue optoelectronic element may be a light emitting diode or a photoelectric conversion diode, and each of the red pixel circuit, the green pixel circuit, and the blue pixel circuit may include a switching thin film transistor, a driving thin film transistor, a capacitor, or a combination thereof.

The panel for the electronic device may further include a control circuit electrically connected to the plurality of unit pixel circuits and including a driver integrated circuit, and the control circuit may overlap with the plurality of unit pixel and the plurality of unit pixel circuit along the thickness direction of the substrate.

The control circuit may include a complementary metal-oxide-semiconductor (CMOS) circuit including a two-dimensional material.

A panel for an electronic device according to some example embodiments includes a substrate, first, second and third optoelectronic elements positioned on the substrate and configured to emit or absorb lights in a red wavelength spectrum, green wavelength spectrum and blue wavelength spectrum, respectively, a first insulation layer positioned on the first, second, and third optoelectronic elements, a first pixel circuit positioned on the first insulation layer and configured to control and drive the first optoelectronic element, a second insulation layer positioned on the first pixel circuit, a second pixel circuit positioned on the second insulation layer and configured to control and drive the second optoelectronic element, a third insulation layer positioned on the second pixel circuit, and a third pixel circuit positioned on the third insulation layer and configured to control and drive the third optoelectronic element. where the first pixel circuit overlaps with the first optoelectronic element along a thickness direction of the substrate and additionally overlaps with at least one of the second optoelectronic element or the third optoelectronic element, the second pixel circuit overlaps with the second optoelectronic element along the thickness direction of the substrate and additionally overlaps with at least one of the first optoelectronic element or the third optoelectronic element, and the third pixel circuit overlaps with the third optoelectronic element along the thickness direction of the substrate and additionally overlaps with at least one of the first optoelectronic element or the second optoelectronic element.

The first pixel circuit may overlap about 50% to about 100% of a total area of the first optoelectronic element, the second optoelectronic element, and the third optoelectronic element, the second pixel circuit may overlap about 50% to about 100% of the total area of the first optoelectronic element, the second optoelectronic element, and the third optoelectronic element, and the third pixel circuit may overlap about 50% to about 100% of the total area of the first optoelectronic element, the second optoelectronic element, and the third optoelectronic element.

Active layers of the first, second, and third pixel circuit may include two-dimensional material, and a thickness of each of the first, second, and third pixel circuits may be about 0.1 nm to about 3 μm.

The panel for the electronic device may further include fourth, fifth and sixth optoelectronic elements positioned adjacent to the first, second and third optoelectronic elements along the direction parallel to a major surface of the substrate and configured to emit or absorb lights in the red wavelength spectrum, green wavelength spectrum, and blue wavelength spectrum, respectively, a fourth insulation layer positioned on the third pixel circuit, a fourth pixel circuit positioned on the fourth insulation layer and configured to control and drive the fourth optoelectronic element, a fifth insulation layer positioned on the fourth pixel circuit, a fifth pixel circuit positioned on the fifth insulation layer and configured to control and drive the fifth optoelectronic element, a sixth insulation layer positioned on the fifth pixel circuit, and a sixth pixel circuit positioned on the sixth insulation layer and configured to control and drive the sixth optoelectronic element, the first pixel circuit, the second pixel circuit, and the third pixel circuit each further overlap with at least one of the fourth optoelectronic element, the fifth optoelectronic element, or the sixth optoelectronic element along the thickness direction of the substrate, the fourth pixel circuit overlaps with the fourth optoelectronic element along the thickness direction of the substrate and additionally overlaps with at least one of the first optoelectronic element, the second optoelectronic element, the third optoelectronic element, the fifth optoelectronic element, or the sixth optoelectronic element, the fifth pixel circuit overlaps with the fifth optoelectronic element along the thickness direction of the substrate and additionally overlaps with at least one of the first optoelectronic element, the second optoelectronic element, the third optoelectronic element, the fourth optoelectronic element, or the sixth optoelectronic element, and the sixth pixel circuit overlaps with the sixth optoelectronic element along the thickness direction of the substrate and additionally overlaps with at least one of the first optoelectronic element, the second optoelectronic element, the third optoelectronic element, the fourth optoelectronic element, or the fifth optoelectronic element.

The panel for the electronic device may further include a control circuit electrically connected to the first, second, and third pixel circuits and including a driver integrated circuit, and the control circuit may overlap with the first, second, and third optoelectronic elements and the first, second, and third pixel circuits along the thickness direction of the substrate.

According to some example embodiments, an electronic device including the panel for the electronic device above-described is provided.

It is possible to implement a high-performance panel such as a high-resolution display panel or a high-sensitivity sensor array panel by reducing the pixel size, while preventing a deterioration of the stability and performance of the pixel circuit.

### BRIEF DESCRIPTION OF THE DRAWINGS

FIG. 1 is a schematic diagram showing an example of a pixel arrangement of a panel for an electronic device according to some example embodiments,

FIG. 2 is a perspective view showing an example of an arrangement of a stack structure A of a unit pixel and a unit pixel circuit of a panel for an electronic device of FIG. 1,

FIG. 3 is a perspective view showing an example of a stack structure A of a unit pixel and a unit pixel circuit of a panel for an electronic device FIG. 2,

FIG. 4 is a top plan view showing an example of a stack structure A of a unit pixel and a unit pixel circuit of a panel for an electronic device of FIG. 2,

FIG. 5 is a cross-sectional view showing an example a stack structure A of a unit pixel and a unit pixel circuit of a panel for an electronic device of FIG. 2,

FIGS. 6A to 6C are top plan views showing examples of an arrangement of each pixel circuit and an optoelectronic element (a sub-pixel) in a stack structure A of a unit pixel and a unit pixel circuit of a panel of an electronic device of FIG. 5,

FIG. 7 is a schematic diagram showing another example of a pixel arrangement of a panel for an electronic device according to some example embodiments,

FIG. 8 is a cross-sectional view showing an example of a stack structure A of a unit pixel and a unit pixel circuit of a panel for an electronic device in FIG. 7,

FIGS. 9A to 9D are top plan views showing examples of an arrangement of each pixel circuit and light sensing device (a sub-pixel) in a stack structure A of a unit pixel and a unit pixel circuit of a panel of an electronic device of FIG. 7 and FIG. 8,

FIG. 10 is a schematic diagram showing another example of a panel for an electronic device according to some example embodiments,

FIG. 11 is a perspective view showing an example of stack structure A including two unit pixels and two unit pixel circuits according to another example of a panel for an electronic device according to some example embodiments, and

FIG. 12 is a cross-sectional view showing an example of a stack structure A including two unit pixels and two unit pixel circuits of a panel of an electronic device of FIG. 11.

### DETAILED DESCRIPTION

Example embodiments will hereinafter be described in detail, and may be easily performed by a person having an ordinary skill in the related art. However, this disclosure may be embodied in many different forms and is not to be construed as limited to the exemplary embodiments set forth herein.

In the drawings, the thickness of layers, films, panels, regions, etc., are exaggerated for clarity. It will be understood that when an element such as a layer, film, region, or substrate is referred to as being “on” another element, it may be directly on the other element or intervening elements may also be present. In contrast, when an element is referred to as being “directly on” another element, there are no intervening elements present.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±10%, 5% or 2% of the stated value.

The drawings and description are to be regarded as illustrative in nature and not restrictive. Like reference numerals designate like elements throughout the specification.

In the following, terms ‘lower’ and ‘upper’ are only for better understanding and ease of description and do not limit a position relationship.

Hereinafter, “a sub-pixel” and “a pixel” may be used interchangeably, and may refer to a minimum unit configured to display a color or detect light of a certain wavelength spectrum (e.g., red, green, or blue wavelength spectrums). For example, a sub-pixel in a display panel may be a minimum unit configured to display a color such as red, green, or blue, and a pixel in a sensor array panel may be a minimum unit configured to detect light in red, green, or blue wavelength spectrum.

Hereinafter, “a unit pixel” may be a minimum unit forming an image by combining a plurality of sub-pixels or a plurality of pixels.

Hereinafter, a panel for an electronic device according to an some example embodiments will be described.

A panel 10 for an electronic device according to one embodiment may be a panel in which a plurality of optoelectronic elements (an optoelectronic elements) capable of displaying colors or detecting light of a predetermined wavelength spectrum are arranged in an array on a substrate, for example a display panel or a sensor array panel.

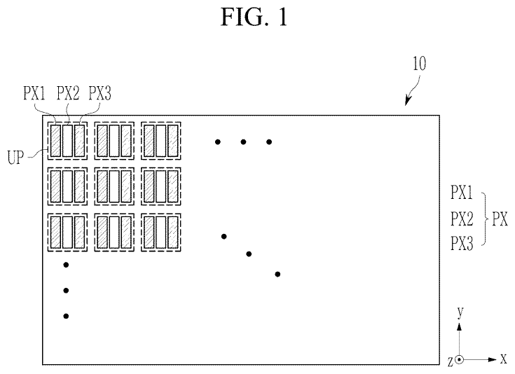

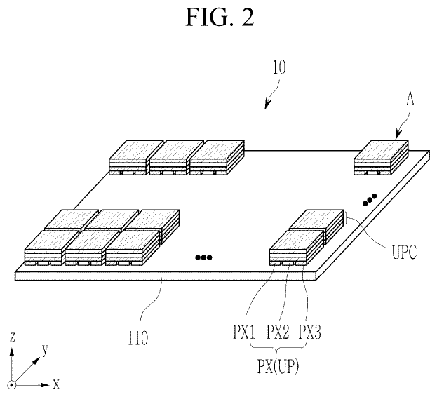

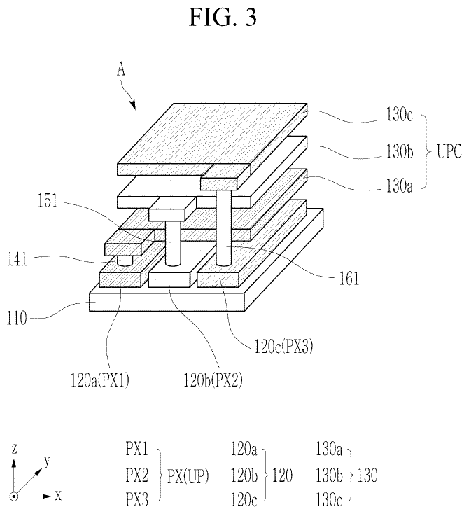

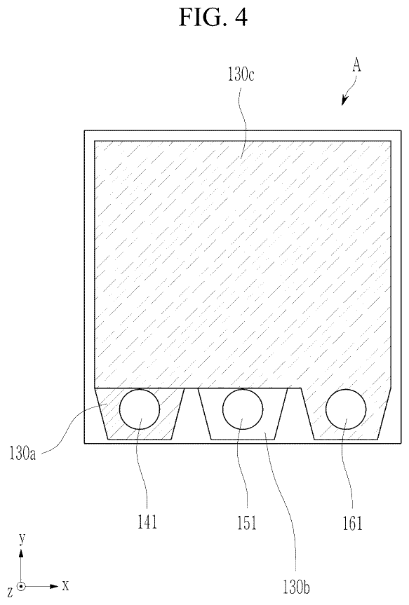

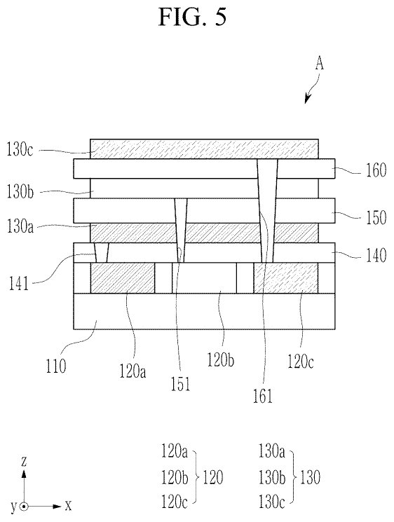

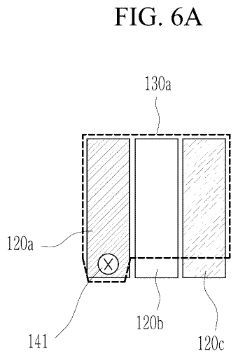

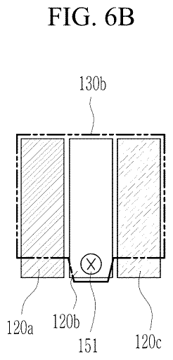

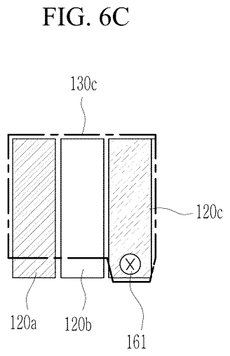

FIG. 1 is a schematic diagram showing an example of a pixel arrangement of a panel for an electronic device according to some example embodiments, FIG. 2 is a perspective view showing an example of an arrangement of a stack structure A of a unit pixel and a unit pixel circuit of a panel for an electronic device of FIG. 1, FIG. 3 is a perspective view showing an example of a stack structure A of a unit pixel and a unit pixel circuit of a panel for an electronic device FIG. 2 (In FIG. 3, insulation layers are omitted for ease of description), FIG. 4 is a top plan view showing an example of a stack structure A of a unit pixel and a unit pixel circuit of a panel for an electronic device of FIG. 2, FIG. 5 is a cross-sectional view showing an example a stack structure A of a unit pixel and a unit pixel circuit of a panel for an electronic device of FIG. 2, and FIG. 6A to 6C are top plan views showing examples of an arrangement of each pixel circuit and an optoelectronic element (a sub-pixel) in a stack structure A of a unit pixel and a unit pixel circuit of a panel of an electronic device of FIG. 5. As used herein, the “top plan view” is a view in a thickness direction (i.e., z direction) of the substrate 110.

Referring to FIG. 1, a panel 10 for an electronic device according to some example embodiments includes a plurality of sub-pixels or pixels PX (hereinafter, called ‘a sub-pixel’) configured to display the same or different colors or detect light of the same or different wavelength spectrum, and the plurality of sub-pixel PX is repeatedly arranged along a row and/or a column of the substrate 110 to form one unit pixel UP, which is a minimum unit configured to display or detect all colors. Each sub-pixel PX may be defined by the optoelectronic element 120, which will be described later.

The unit pixel UP includes a first sub-pixel PX1, a second sub-pixel PX2, and a third sub-pixel PX3, which display or detect different first, second, and third colors selected from red, green, and blue. For example, the first color, the second color, and the third color may be red, green, and blue, respectively, the first sub-pixel PX1 may be a red sub-pixel configured to display red color or detect light in a red wavelength spectrum, and the second sub-pixel PX2 may a green sub-pixel configured to display green color or detect light in a green wavelength spectrum, and the third sub-pixel PX3 may be a blue sub-pixel configured to display blue color or detect light in a blue wavelength spectrum. The area occupied by the plurality of sub-pixels PX and configured to display or detect color by the plurality of sub-pixel PX may be a display area or a sensing area.

The unit pixel UP may include at least one first sub-pixel PX1, at least one second sub-pixel PX2, and at least one third sub-pixel PX3, and may further additionally include an auxiliary sub-pixel such as a white sub-pixel (not shown). For example, FIG. 1 shows an example in which one first sub-pixel PX1, one second sub-pixel PX2, and one third sub-pixel PX3 form the unit pixel UP. However, it is not limited to this, and the arrangement of the unit pixel UP may vary, and the shape, number, size, and arrangement of the sub-pixels PX included in each unit pixel UP may vary.

Referring to FIG. 2, the panel 10 for the electronic device according to some example embodiments includes a substrate 110, and a plurality of unit pixels UP and a plurality of unit pixel circuits UPC repeatedly arranged on the substrate 110.

The substrate 110 may be a support substrate for the panel 10 for the electronic device and may be, for example, a glass substrate, a polymer substrate or a silicon substrate. The polymer substrate, for example, may include polycarbonate, polymethylmethacrylate, polyethylene terephthalate, polyethylene naphthalate, polyimide, polyamide, polyamide-imide (PAI), polyethersulfone (PES), polyorganosiloxane, styrene-ethylene-butylene-styrene, polyurethane, polyacryl, polyolefin or combination thereof, but it is not limited thereto.

The unit pixel UP and the unit pixel circuit UPC are stacked together along the thickness direction (e.g., a z direction) of the substrate 110, and one unit pixel UP and one unit pixel circuit UPC stacked together form one unit stack structure A, and are repeatedly arranged along the direction parallel to a major surface (e.g., any direction on an xy plane) of the substrate 110.

Each unit pixel UP, like the pixel arrangement shown in FIG. 1, may include one first sub-pixel PX1, one second sub-pixel PX2, and one third sub-pixel PX3, and the first sub-pixel PX1, the second sub-pixel PX2, and the third sub-pixel PX3 may be configured to display or detect the different first, second, and third colors selected from red, green, and blue. Below, for better understanding and ease of description, the first sub-pixel PX1, the second sub-pixel PX2, and the third sub-pixel PX3 are described as a red sub-pixel, a green sub-pixel, and a blue sub-pixel, respectively, as examples, but it is not limited thereto. The first sub-pixel PX1, the second sub-pixel PX2, and the third sub-pixel PX3 are arranged side by side along the row and/or the column of the substrate 110, and for example are arranged side by side along the direction parallel to a major surface (e.g., the any direction on an xy plane) of the substrate 110.

Referring to FIG. 3 to FIG. 5 along with FIG. 1 and FIG. 2, each of the first, second, and third sub-pixels PX1, PX2, and PX3 may include a optoelectronic element 120, and the optoelectronic element 120 may be, for example, a light emitting element configured to display color by emitting light of a predetermined wavelength spectrum, or a photoelectric conversion element configured to detect color by absorbing light of a predetermined wavelength spectrum and electrically converting the absorbed light. The light emitting region by the light emitting element or the light absorbing region by the photoelectric conversion element may define each sub-pixel PX.

The optoelectronic element 120 may include a first optoelectronic element 120a positioned within the first sub-pixel PX1, a second optoelectronic element 120b positioned within the second sub-pixel PX2, and a third optoelectronic element 120c positioned within the third sub-pixel PX3. The first optoelectronic element 120a may be a light emitting element or a photoelectric conversion element configured to emit or absorb light of the first color (e.g., red) displayed or detected by the first sub-pixel PX1, the second optoelectronic element 120b may be a light emitting element or a photoelectric conversion element configured to emit or absorb light of the second color (e.g., green) displayed or detected by the second sub-pixel PX2, and the third optoelectronic element 120c may be a light emitting element or a photoelectric conversion element configured to emit or absorb light of a third color (e.g., blue) displayed or detected by the third sub-pixel PX3.

The light emitting element may be, for example, a light emitting diode, and the photoelectric conversion element may be, for example, a photoelectric diode. The light emitting diode may be, for example, an organic light emitting diode, an inorganic light emitting diode, a quantum dot light emitting diode or a micro light emitting diode, and the photoelectric diode, for example, may be an organic photoelectric diode, an inorganic photoelectric diode, an organic/inorganic photoelectric diode, a quantum dot photoelectric diode or a perovskite photoelectric diode, but it is not limited thereto.

The light emitting diode may include a light emitting layer configured to emit light of a predetermined wavelength spectrum between a pair of electrodes, and the light emitting layer may include an organic light emitting material, an inorganic light emitting material, an organic/inorganic light emitting material, or a combination thereof. The color displayed by the optoelectronic element 120 may be determined according to the light emitting spectrum of the light emitted from the light emitting layer, for example, the maximum light emitting wavelength of the light emitted from the light emitting layer of the first optoelectronic element 120a configured to display red, the second optoelectronic element 120b configured to display green, and the third optoelectronic element 120c configured to display blue, may be each greater than about 600 nm and less than about 750 nm, about the range of about 500 nm to about 600 nm, and greater than or equal to about 380 nm and less than about 500 nm.

The photoelectric diode may include a photoelectric conversion layer configured to absorb light of a predetermined wavelength spectrum between the pair of electrodes, and the photoelectric conversion layer may include an organic photoelectric conversion material, an inorganic photoelectric conversion material, an organic/inorganic photoelectric conversion material, or a combination thereof. Depending on the absorption spectrum of light absorbed by the photoelectric conversion layer, the color detected by the optoelectronic element 120 may be determined, for example, the maximum absorption wavelength of light absorbed in the photoelectric conversion layer of the first optoelectronic element 120a configured to detect light in the red wavelength spectrum, the second optoelectronic element 120b configured to detect light in the green wavelength spectrum, and the third optoelectronic element 120c configured to detect light in the blue wavelength spectrum may be greater than about 600 nm and less than 750 nm, about 500 nm to about 600 nm, and great than or equal to about 380 nm and less than about 500 nm, respectively.

The unit pixel circuit UPC includes a plurality of pixel circuits 130 that individually controls and/or drives each optoelectronic element 120a, 120b, and 120c included in the unit pixel UP. For example, the unit pixel circuit UPC includes a first pixel circuit 130a (e.g., a red pixel circuit) electrically connected to the first optoelectronic element 120a and controlling and/or driving the first optoelectronic element 120a, a second pixel circuit 130b (e.g., a green pixel circuit) electrically connected to the second optoelectronic element 120b and controlling and/or driving the second optoelectronic element 120b, and a third pixel circuit 130c (e.g., a blue pixel circuit) electrically connected to the third optoelectronic element 120c and controlling and/or driving the third optoelectronic element 120c.

Each of the first pixel circuit 130a, the second pixel circuit 130b, and the third pixel circuit 130c may include at least one switching thin film transistor (a switching TFT), at least one driving thin film transistor (a driving TFT), at least one capacitor (a capacitor), or a combination thereof.

The switching thin film transistor may be electrically connected to a gate line configured to transmit a gate signal (or a scan signal) and a data line configured to transmit a data signal, and the driving thin film transistor may be electrically connected to the switching thin film transistor and the first, second or third optoelectronic elements 120a, 120b, and 120c. described above. The switching thin film transistor and the driving thin film transistor may each include a control terminal, an input terminal, an output terminal, and an active layer.

The active layer included in the first pixel circuit 130a, second pixel circuit 130b, and third pixel circuit 130c may include, for example, a two-dimensional material, oxide, silicon, an organic material, or a combination thereof.

The two-dimensional material may be a plate-shaped or a sheet-shaped material, for example, it may be a single element, a multi element compound, an organic compound, an organic/inorganic compound, or a combination thereof, for example, it may be a two-dimensional inorganic compound, graphene, borophene, germanene, stanene, phosphorene, bismuthene, tellurene, metal chalcogenide, boron nitride, black phosphorus, a two-dimensional organic compound, a two-dimensional organic/inorganic compound, or a combination thereof. The metal chalcogenide, for example, may be MoS₂, WS₂, MoSe₂ and/or WSe₂, the two-dimensional organic compound may be a covalent-organic framework COF, and the two-dimensional organic/inorganic compound may be a metal-organic framework MOF, but it is not limited thereto.

The two-dimensional material may be grown or deposited as a monolayer or 2 to 10 monolayers, for example, thereby realizing a very thin active layer with a thickness of about 0.1 nm to about 100 nm.

Oxide may be a metal oxide including indium, gallium, tin, zinc or combination thereof, for example, may include indium-gallium-zinc oxide, indium-gallium-tin oxide, or a combination thereof.

Oxide may realize a relatively thin active layer with a thickness of about 1 nm to about 1 μm, for example.

For example, the active layer may include a material configured to be grown or deposited at relatively low temperatures, accordingly, in the formation step of the active layer of first pixel circuit 130a, the second pixel circuit 130b, and/or the third pixel circuit 130c, it is possible to prevent the first, second, and third optoelectronic elements 120a, 120b, and 120c positioned below the first pixel circuit 130a, second pixel circuit 130b and/or third pixel circuit 130c from being damaged by heat.

For example, the active layer may include a material configured to be grown or deposited at a temperatures below about 400° C., and may include a material configured to be grown or deposited at a temperatures ranging from about 25° C. to about 400° C., about 30° C. to about 400° C., and about 50° C. to about 400° C., about 50° C. to about 350° C., and about 50° C. to about 300° C. within the range. For example, the active layer may include a two-dimensional material configured to be grown or deposited at temperatures below about 400° C., and may include two-dimensional materials configured to be grown or deposited at temperatures of about 25° C. to about 400° C., about 30° C. to about 400° C., about 50° C. to about 400° C., about 50° C. to about 350° C., and about 50° C. to about 300° C. within the range. For example, the active layer may include a monocrystalline or monocrystalline-like two-dimensional material configured to be grown or deposited at temperatures below about 400° C., and may include a monocrystalline or monocrystalline-like two-dimensional material configured to be grown or deposited at temperatures of about 25° C. to about 400° C., about 30° C. to about 400° C., about 50° C. to about 400° C., about 50° C. to about 350° C., about 50° C. to about 300° C. within the range.

The first pixel circuit 130a, second pixel circuit 130b, and third pixel circuit 130c may be arranged to overlap each other under and above the first, second, and third optoelectronic elements 120a, 120b, and 120c, that is, the unit pixel UP including the first, second, and third optoelectronic elements 120a, 120b, and 120c, the first pixel circuit 130a, the second pixel circuit 130b, and the third pixel circuit 130c may be stacked to each other in the thickness direction (e.g., the z direction) of the substrate 110. In the drawing, the structure in which the unit pixel circuit UPC including the first, second, and third pixel circuits 130a, 130b, and 130c is positioned on the unit pixel UP including the first, second, and third optoelectronic element 120a, 120b, and 120c is described, but it is not limited thereto, and the unit pixel circuit UPC may be positioned under the unit pixel UP.

The unit pixel UP, the first pixel circuit 130a, the second pixel circuit 130b, and the third pixel circuit 130c are separated by the first, second or third insulation layers 140, 150, and 160. That is, the unit pixel UP including the first, second, and third optoelectronic element 120a, 120b, and 120c, the first insulation layer 140, the first pixel circuit 130a, the second insulation layer 150, the second pixel circuit 130b, the third insulation layer 160, and the third pixel circuit 130c are sequentially stacked along the thickness direction (e.g., the z direction) of the substrate 110.

The first, second and third insulation layers 140, 150, and 160 each have some of a first, second and/or third via-hole 141, 151, and 161 exposing the first optoelectronic element 120a, the second optoelectronic element 120b, and/or the third optoelectronic element 120c, respectively. The first via-hole 141 may penetrate from the first optoelectronic element 120a to the first pixel circuit 130a, the second via-hole 151 may penetrate from the second optoelectronic element 120b to the second pixel circuit 130b, the third via-hole 161 may penetrate from the third optoelectronic element 120c to the third pixel circuit 130c, and the first, second, and third via-holes 141, 151, and 161 may each be filled with a conductor. In other words, the first to third via-holes 141, 151 and 161 may penetrate the first insulation layer 140, the second and third via-holes 151 and 161 may penetrate the second insulation layer 150, and the third via-hole 161 may penetrate the third insulation layer 160.

In this way, the first pixel circuit 130a, the second pixel circuit 130b, and the third pixel circuit 130c are stacked on each other in the thickness direction (e.g., the z direction) of the substrate 110, and thus the available area per pixel circuit may be expanded compared to a structure in which the first to third pixel circuits are disposed in the same layer.

If the first pixel circuit 130a, the second pixel circuit 130b, and the third pixel circuit 130c are arranged side by side in the direction parallel to a major surface (e.g., any direction on an xy plane) of the substrate 110, corresponding to the first optoelectronic element 120a, the second optoelectronic element 120b, and the third optoelectronic element 120c, respectively, the areas occupied by the first pixel circuit 130a, the second pixel circuit 130b, and the third pixel circuit 130c may be limited to being equal to or smaller than the areas of the corresponding first optoelectronic element 120a, the second optoelectronic element 120b, and the third optoelectronic element 120c, that is, the areas occupied by the first sub-pixel PX1, the second sub-pixel PX2, and the third sub-pixel PX3, accordingly, when the size of the first, second, and third sub-pixels PX1, PX2, and PX3 is reduced in order to increase the number of the pixels per a unit area, the areas of the first, second, and third pixel circuits 130a, 130b, and 130c must also be reduced.

However, as above-described, as the first pixel circuit 130a, the second pixel circuit 130b, and the third pixel circuit 130c are stacked on each other in the thickness direction (e.g., the z direction) of the substrate 110, while the size of the first, second, and third sub-pixels PX1, PX2, and PX3 is not limited, the area occupied by the pixel circuits that may be used within each unit pixel UP may be expanded. Accordingly, even when reducing the size of the first, second, and third sub-pixels PX1, PX2, and PX3 to increase the number of the pixels per unit area, the areas of the first, second, and third pixel circuits 130a, 130b, and 130c may be independently secured, thereby reducing restrictions on the process for forming the first, second, and third pixel circuits 130a, 130b, and 130c, and effectively preventing performance and stability deterioration of the first, second, and third pixel circuits 130a, 130b, and 130c.

For example, each area of the first pixel circuit 130a, the second pixel circuit 130b or the third pixel circuit 130c may be wider than the area of the corresponding first optoelectronic element 120a, second optoelectronic element 120b or third optoelectronic element 120c, respectively.

For example, the first pixel circuit 130a may overlap the first optoelectronic element 120a along the thickness direction (e.g., the z direction) of the substrate 110 and may additionally overlap at least one of the second optoelectronic element 120b or the third optoelectronic element 120c. For example, as shown in FIG. 6A, the first pixel circuit 130a may overlap substantially all the first optoelectronic element 120a, the second optoelectronic element 120b, and the third optoelectronic element 120c, the area of the first pixel circuit 130a may be up to three times of the area of the first optoelectronic element 120a. For example, the first pixel circuit 130a may overlap with about 50% to about 100% of the total area of the first optoelectronic element 120a, the second optoelectronic element 120b, and the third optoelectronic element 120c, or may overlap with about 60% to 99%, about 65% to 98%, about 70% to 95%, about 75% to 95% or about 80% to 95% of the total area of the first optoelectronic element 120a, the second optoelectronic element 120b, and the third optoelectronic element 120c within the range in the plan view.

For example, the second pixel circuit 130b may overlap the second optoelectronic element 120b along the thickness direction (e.g., the z direction) of the substrate 110, and may additionally overlap at least one of the first optoelectronic element 120a or the third optoelectronic element 120c. For example, as shown in FIG. 6B, the second pixel circuit 130b may overlap substantially all the second optoelectronic element 120b, the first optoelectronic element 120a, and the third optoelectronic element 120c along the thickness direction (e.g., the z direction) of the substrate 110, the area of the second pixel circuit 130b may be up to three times of the area of the second optoelectronic element 120b. For example, the second pixel circuit 130b may overlap with about 50% to about 100% of the total area of the first optoelectronic element 120a, the second optoelectronic element 120b, and the third optoelectronic element 120c, or may overlap with about 60% to about 99%, about 65% to about 98%, about 70% to about 95%, about 75% to about 95% or about 80% to about 95% of the total area of the first optoelectronic element 120a, the second optoelectronic element 120b, and the third optoelectronic element 120c within the range in the plan view.

For example, the third pixel circuit 130c may overlap the third optoelectronic element 120c along the thickness direction (e.g., the z direction) of the substrate 110, and may additionally overlap at least one of the first optoelectronic element 120a or the second optoelectronic element 120b. For example, as shown in FIG. 6C, the third pixel circuit 130c may overlap the third optoelectronic element 120c, the first optoelectronic element 120a, and the second optoelectronic element 120b along the thickness direction (e.g., the z direction) of the substrate 110, and the area of the third pixel circuit 130c may be up to three times of the area of the third optoelectronic element 120c. For example, the third pixel circuit 130c may overlap with about 50% to about 100% of the total area of the first optoelectronic element 120a, the second optoelectronic element 120b, and the third optoelectronic element 120c, or may overlap with about 60% to about 99%, about 65% to about 98%, about 70% to about 95%, about 75% to about 95% or about 80% to about 95% of the total area of the first optoelectronic element 120a, the second optoelectronic element 120b, and the third optoelectronic element 120c within the range in the plan view.

Each of the first pixel circuit 130a, the second pixel circuit 130b, and the third pixel circuit 130c may have a relatively thin thickness, for example about 0.1 nm to about 100 nm, and may have the thickness of about 1 nm to about 80 nm, about 1 nm to about 60 nm, about 1 nm to about 50 nm, about 1 nm to about 30 nm, about 1 nm to about 25 nm, about 1 nm to about 20 nm or about 3 nm to about 20 nm, within the range. By this way, as the first, second, and third pixel circuits 130a, 130b, and 130c have the relatively thin thicknesses, as described above, even if the first pixel circuit 130a, the second pixel circuit 130b, and the third pixel circuit 130c are stacked in the thickness direction (e.g., the z direction), the relatively thin panel may be implemented without significantly increasing the thickness of the panel 10 for the electronic device.

The panel 10 for the electronic device may further include a control circuit (not shown) including a driver integrated circuit. The driver integrated circuit may include a scan driver and a data driver. The scan driver and the data driver may be each electrically connected to the plurality of unit pixel circuits UPC, and may be placed in a region other than a display area or a sensing area.

Hereinafter, the panel for the electronic device according to another example embodiment of some example embodiments will be described.

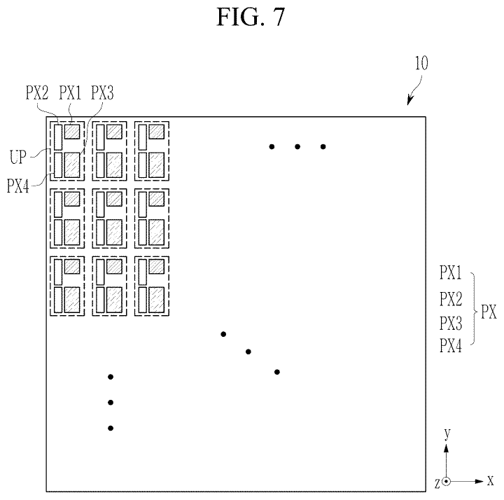

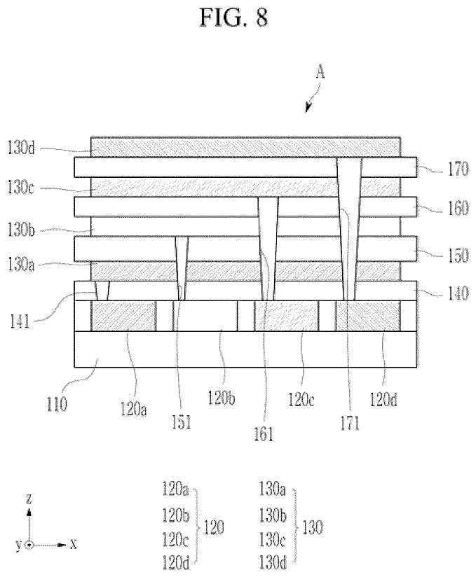

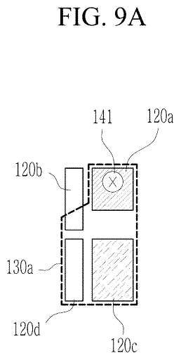

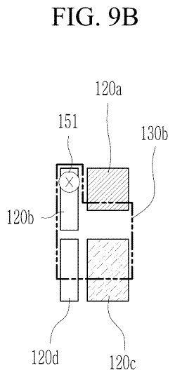

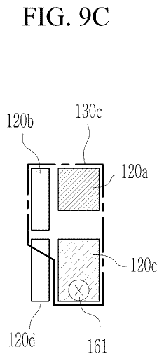

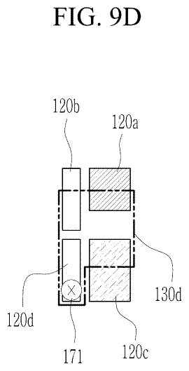

FIG. 7 is a schematic diagram showing another example of a pixel arrangement of a panel for an electronic device according to some example embodiments, FIG. 8 is a cross-sectional view showing an example of a stack structure A of a unit pixel and a unit pixel circuit of a panel for an electronic device in FIG. 7, and FIGS. 9A to 9D are top plan views showing examples of an arrangement of each pixel circuit and light sensing device (a sub-pixel) in a stack structure A of a unit pixel and a unit pixel circuit of a panel of an electronic device of FIG. 7 and FIG. 8.

Referring to FIG. 7, the panel 10 for the electronic device according to the present embodiment, like the above-described embodiment, includes a plurality of sub-pixels PX configured to display the same or different colors or detect light of the same or different color wavelength spectrum, and the plurality of sub-pixels PX form one unit pixel UP and are repeatedly arranged along the rows and/or columns of the substrate 110.

However, in the panel 10 for the electronic device according to the present embodiment, unlike the above-described embodiment, each unit pixel UP further includes a fourth sub-pixel PX4 in addition to the first, second, and third sub-pixels PX1, PX2, and PX3. The first sub-pixel PX1 may be a red sub-pixel configured to display or detect red, the second sub-pixel PX2 and the fourth sub-pixel PX4 may be a green sub-pixel configured to display or detect green, and the third sub-pixel PX3 may be a blue sub-pixel configured to display or detect blue. However, it is not limited to this, and the fourth sub-pixel PX4 may be a red sub-pixel or a blue sub-pixel. The arrangement of the unit pixel UP may vary, and the shape, number, size, and arrangement of the sub-pixels PX included in each unit pixel UP may vary.

Referring to FIG. 8, each of the first, second, third, and fourth sub-pixels PX1, PX2, PX3, and PX4 may include the optoelectronic element 120 selected from a light emitting element and the photoelectric conversion element. In detail, the optoelectronic element 120 includes a first optoelectronic element 120a positioned in the first sub-pixel PX1, a second optoelectronic element 120b positioned in the second sub-pixel PX2, a third optoelectronic element 120c positioned in the third sub-pixel PX3, and a fourth optoelectronic element 120d positioned in the fourth sub-pixel PX4, the first optoelectronic element 120a may be a light emitting element or a photoelectric conversion element configured to emit or absorb light of the first color (e.g., red) displayed by the first sub-pixel PX1, the second optoelectronic element 120b and the fourth optoelectronic element 120d may be a light emitting element or a photoelectric conversion element configured to emit or absorb light of the second color (e.g., green) displayed by the second sub-pixel PX2 and the fourth sub-pixel PX4, respectively, and the third optoelectronic element 120c may be a light emitting element or a photoelectric conversion element configured to emit or absorb light of the third color (e.g., blue) displayed by the third sub-pixel PX3. The descriptions of the light emitting element and the photoelectric conversion element are as described above.

The unit pixel circuit UPC includes a plurality of pixel circuit 130 configured to individually control and/or drive the optoelectronic element 120 included in the unit pixel UP. For example, the unit pixel circuit UPC may include a first pixel circuit 130a electrically connected to the first optoelectronic element 120a and controlling and/or driving the first optoelectronic element 120a, a second pixel circuit 130b electrically connected to the second optoelectronic element 120b and controlling and/or driving the second optoelectronic element 120b, a third pixel circuit 130c electrically connected to the third optoelectronic element 120c and controlling and/or driving the third optoelectronic element 120c, and a fourth pixel circuit 130d electrically connected to the fourth optoelectronic element 120d and controlling and/or driving the fourth optoelectronic element 120d. The descriptions of the first, second, and third pixel circuits 130a, 130b, and 130c are as described above, the fourth pixel circuit 130d may also include at least one switching thin film transistor, at least one driving thin film transistor, at least one capacitor, or a combination thereof, and the active layer included in the fourth pixel circuit 130d is the same as that the above-described active layer.

The unit pixel UP including the first, second, third, and fourth optoelectronic elements 120a, 120b, 120c, and 120d, the first pixel circuit 130a, the second pixel circuit 130b, the third pixel circuit 130c, and the fourth pixel circuit 130d are stacked to each other in the thickness direction (e.g., the z direction) of the substrate 110, and the unit pixel UP, the first pixel circuit 130a, the second pixel circuit 130b, the third pixel circuit 130c, and the fourth pixel circuit 130d are divided by the first, second, third, and fourth insulation layers 140, 150, 160, and 170.

The first, second, third and/or fourth insulation layers 140, 150, 160, 170 have first, second, third, and fourth via-holes 141, 151, 161, and 171 exposing the first, second, third, and fourth optoelectronic elements 120a, 120b, 120c, and 120d. The first via-hole 141 may penetrate from the first optoelectronic element 120a to the first pixel circuit 130a, the second via-hole 151 may penetrate from the second optoelectronic element 120b to the second pixel circuit 130b, the third via-hole 161 may penetrate from the third optoelectronic element 120c to the third pixel circuit 130c, the fourth via-hole 171 may penetrate from the fourth optoelectronic element 120d to the fourth pixel circuit 130d, and the first, second, third and fourth via-holes 141, 151, 161, and 171 may each be filled with a conductor.

As above-described, as the first pixel circuit 130a, the second pixel circuit 130b, the third pixel circuit 130c, and the fourth pixel circuit 130d are stacked in the thickness direction (e.g., the z direction) of the substrate 110, the area of the pixel circuit that may be used in each unit pixel UP may be expanded. Accordingly, even when reducing the size of the first, second, third, and fourth sub-pixels PX1, PX2, PX3, and PX4 to increase the number of the pixels per unit area, the areas occupied by the first, second, third, and fourth pixel circuits 130a, 130b, 130c, and 130d may be independently secured, thereby reducing restrictions on the process for forming the first, second, third, and fourth pixel circuits 130a, 130b, 130c, and 130d, and effectively preventing performance and stability deterioration of the first, second, third, and fourth pixel circuits 130a, 130b, 130c, and 130d.

As an example, areas of the first pixel circuit 130a, the second pixel circuit 130b, the third pixel circuit 130c, and the fourth pixel circuit 130d may be wider than the areas of the corresponding first optoelectronic element 120a, second optoelectronic element 120b, third optoelectronic element 120c, and fourth optoelectronic element 120d, respectively.

For example, the first pixel circuit 130a may overlap the first optoelectronic element 120a along the thickness direction (e.g., the z direction) of the substrate 110, and may additionally overlap at least one of the second optoelectronic element 120b, the third optoelectronic element 120c, or the fourth optoelectronic element. For example, as shown in FIG. 9A, the first pixel circuit 130a may overlap the first optoelectronic element 120a, the second optoelectronic element 120b, the third optoelectronic element 120c, and the fourth optoelectronic element 120d, along the thickness direction (e.g., the z direction) of the substrate 110. For example, the first pixel circuit 130a may overlap with about 50% to about 100% of the total area of the first optoelectronic element 120a, the second optoelectronic element 120b, the third optoelectronic element 120c, and the fourth optoelectronic element 120d, or may overlap with about 60% to about 99%, about 65% to about 98%, about 70% to about 95%, about 75% to about 95% or about 80% to about 95% of the total area of the first optoelectronic element 120a, the second optoelectronic element 120b, the third optoelectronic element 120c, and the fourth optoelectronic element 120d within the range in the plan view.

For example, the second pixel circuit 130b may overlap with the second optoelectronic element 120b along the thickness direction (e.g., the z direction) of the substrate 110, and may additionally overlap with at least one of the first optoelectronic element 120a, the third optoelectronic element 120c, or the fourth optoelectronic element 120d. For example, as shown in FIG. 9B, the second pixel circuit 130b may overlap the second optoelectronic element 120b, the first optoelectronic element 120a, the third optoelectronic element 120c, and the fourth optoelectronic element 120d along the thickness direction (e.g., the z direction) of the substrate 110. For example, the second pixel circuit 130b may overlap with about 50% to about 100% of the total area of first optoelectronic element 120a, the second optoelectronic element 120b, the third optoelectronic element 120c, and the fourth optoelectronic element 120d, or overlap with about 60% to about 99%, about 65% to about 98%, about 70% to about 95%, about 75% to about 95% or about 80% to about 95% of the total area of the first optoelectronic element 120a, the second optoelectronic element 120b, the third optoelectronic element 120c, and the fourth optoelectronic element 120d within the range in the plan view.

For example, the third pixel circuit 130c may overlap with the third optoelectronic element 120c along the thickness direction (e.g., the z direction) of the substrate 110, and may additionally overlap with at least one of the first optoelectronic element 120a, the second optoelectronic element 120b, or the fourth optoelectronic element 120d. For example, as shown in FIG. 9C, the third pixel circuit 130c may overlap with the third optoelectronic element 120c, the first optoelectronic element 120a, the second optoelectronic element 120b, and the fourth optoelectronic element 120d, along the thickness direction (e.g., the z direction) of the substrate 110. For example, the third pixel circuit 130c may overlap with about 50% to about 100% of the total area of the first optoelectronic element 120a, the second optoelectronic element 120b, the third optoelectronic element 120c, and the fourth optoelectronic element 120d, or overlap with about 60% to about 99%, about 65% to about 98%, about 70% to about 95%, about 75% to about 95% or about 80% to about 95%, of the total area of the first optoelectronic element 120a, the second optoelectronic element 120b, the third optoelectronic element 120c, and the fourth optoelectronic element 120d within the range in the plan view.

For example, the fourth pixel circuit 130d may overlap with the fourth optoelectronic element 120d along the thickness direction (e.g., the z direction) of the substrate 110, and may additionally overlap with at least one of the first optoelectronic element 120a, the second optoelectronic element 120b, or the third optoelectronic element 120c. For example, as shown in FIG. 9D, the fourth pixel circuit 130d may overlap with the fourth optoelectronic element 120d, the first optoelectronic element 120a, the second optoelectronic element 120b, and the third optoelectronic element 120c, along the thickness direction (e.g., the z direction) of the substrate 110. For example, the fourth pixel circuit 130d may overlap with about 50% to about 100% of the total area of the first optoelectronic element 120a, the second optoelectronic element 120b, the third optoelectronic element 120c, and the fourth optoelectronic element 120d, or overlap with about 60% to about 99%, about 65% to about 98%, about 70% to about 95%, about 75% to about 95% or about 80% to about 95% of the total area of the first optoelectronic element 120a, the second optoelectronic element 120b, the third optoelectronic element 120c, and the fourth optoelectronic element 120d, within the range in the plan view.

Each of the first pixel circuit 130a, the second pixel circuit 130b, the third pixel circuit 130c, and the fourth pixel circuit 130d may have a relatively thin thickness, for example about 0.1 nm to about 3 μm, and have a thickness of about 1 nm to about 3 μm, about 10 nm to about 2 μm, about 10 nm to about 1 μm, about 20 nm to about 700 nm, about 20 nm to about 500 nm or about 20 nm to about 300 nm, within the range.

Hereinafter, the panel for the electronic device according to another example embodiment of some example embodiments will be described.

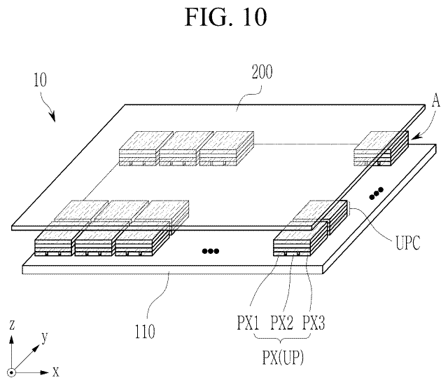

FIG. 10 is a schematic diagram showing another example of a panel for an electronic device according to another example embodiment of some example embodiments.

Referring to FIG. 10, the panel 10 for the electronic device according to the present embodiment, like the embodiment above-described, includes a substrate 110, and a plurality of unit pixels UP and a plurality of unit pixel circuits UPC repeatedly arranged on the substrate 110. The unit pixel UP and the unit pixel circuit UPC are stacked together along the thickness direction (e.g., the z direction) of the substrate 110, and one unit pixel UP and one pixel circuit UPC stacked together form one unit stack structure A and are arranged repeatedly along the direction parallel to a major surface (e.g., any direction on an xy plane) of the substrate 110. FIG. 10 shows the pixel arrangement shown in FIG. 1 as one example, but it is not limited thereto, and it may be equally applied to the pixel array shown in FIG. 7 or to various other pixel arrays.

However, the panel 10 for the electronic device according to the present embodiment, unlike the above-described embodiment, includes a control circuit 200 overlapping a plurality of unit pixel UP and a plurality of unit pixel circuits UPC along the thickness direction (e.g., the z direction) of the substrate 110.

The control circuit 200 includes a driver integrated circuit including a scan driver and a data driver, and is electrically connected to the plurality of unit pixel circuits UPC. The control circuit 200 may include a complementary metal-oxide-semiconductor (CMOS) circuit including the two-dimensional material described above, for example, and accordingly, the control circuit 200 may also have a relatively thin thickness. For example, the thickness of the control circuit 200 may be less than about 1 μm, and within the range, it may be about 10 nm to about 1 μm, about 10 nm to about 800 nm or about 10 nm to about 500 nm.

By placing the control circuit 200 with a relatively thin thickness in the display area or the sensing area where the plurality of unit pixel UP and the plurality of unit pixel circuits UPC are arranged, the relatively thin panel may be implemented without significantly increasing the thickness of the panel 10 for the electronic device. In addition, there is no need to prepare a separate region to place the control circuit 200 in a region (e.g., a border region) other than the display area or the sensing area of the panel 10 for the electronic device, thereby implementing a slim bezel or bezel-free display panel or sensor array panel.

Hereinafter, the panel for the electronic device according to another example embodiment of some example embodiments will be described.

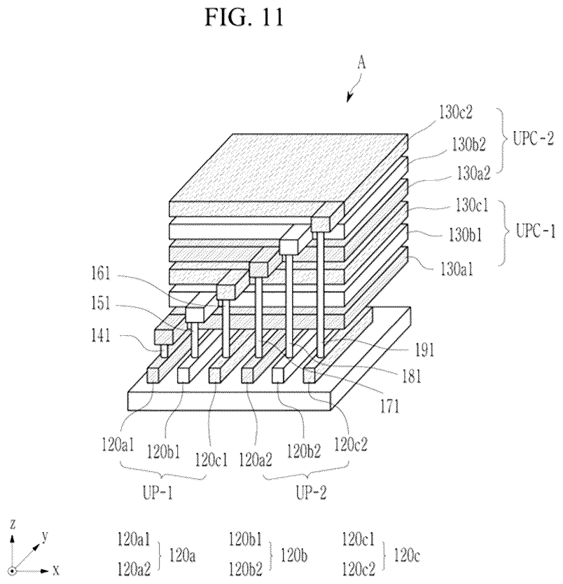

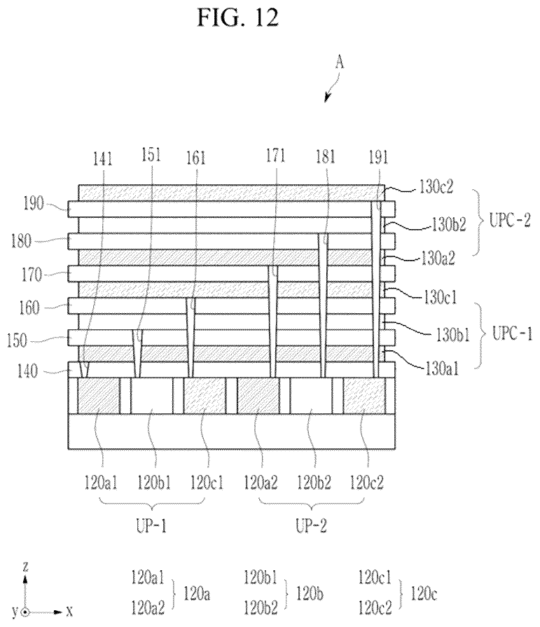

FIG. 11 is a perspective view showing an example of stack structure A including two unit pixels and two unit pixel circuits according to another example of a panel for an electronic device according to some example embodiments (In FIG. 11, insulation layers are omitted for ease of description), and FIG. 12 is a cross-sectional view showing an example of a stack structure A including two unit pixels and two unit pixel circuits of a panel of an electronic device of FIG. 11.

In the panel 10 for the electronic device according to the present embodiment, unlike the above-described embodiment, one unit pixel circuit UPC is stacked with two or more unit pixels UP. For example, the plurality of unit pixels UP includes a first unit pixel UP-1 and a second unit pixel UP-2 positioned adjacently in the direction parallel to a major surface (e.g., any direction on an xy plane) of the substrate 110, and each unit pixel circuit UPC may overlap the first unit pixel UP-1 and the second unit pixel UP-2 along the thickness direction (e.g., the z direction) of the substrate 110.

Referring to FIG. 11 and FIG. 12, a first unit pixel circuit UPC1 and a second unit pixel circuit UPC2 include a plurality of pixel circuits 130a1, 130b1, 130c1, 130a2, 130b2, and 130c2 for independently controlling and/or driving a first, second, and third optoelectronic elements 120a1, 120b1, 120c1, 120a2, 120b2, and 120c2 included in the first and second unit pixels UP-1 and UP-2, respectively. For example, the first unit pixel circuit UPC1 includes the first, second, and third pixel circuits 130a1, 130b1, and 130c1 electrically connected to the first, second, and third optoelectronic elements 120a1, 120b1, and 120c1 included in the first unit pixel UP-1, respectively, for controlling and/or driving them, and the second unit pixel circuit UPC2 includes fourth, fifth, and sixth pixel circuits 130a2, 130b2, and 130c2 electrically connected to the fourth, fifth, and sixth optoelectronic elements 120a2, 120b2, and 120c2 included in the second unit pixel UP-2, respectively, for controlling and/or driving them, and the first unit pixel circuit UPC1 including the first, second, and third pixel circuits 130a1, 130b1, and 130c1 and the second unit pixel circuit UPC2 including the fourth, fifth, and sixth pixel circuits 130a2, 130b2, and 130c2 are stacked each other in the thickness direction of the substrate 110.

The first and second unit pixels UP-1 and UP-2 and the first to sixth pixel circuits 130a1, 130b1, 130c1, 130a2, 130b2, and 130c2 are separated by the first to sixth insulation layers 140, 150, 160, 170, 180, and 190, and the first to sixth insulation layers 140, 150, 160, 170, 180, and 190 have first to sixth via-holes 141, 151, 161, 171, 181, and 191 exposing the first and second unit pixels UP-1 and UP-2 and the first to sixth pixel circuits 130a1, 130b1, 130c1, 130a2, 130b2, and 130c2. The first via-hole 141 may penetrate from the first optoelectronic element 120a1 of the first unit pixel UP-1 to the first pixel circuit 130a1, the second via-hole 151 may penetrate from the second optoelectronic element 120b1 of the first unit pixel UP-1 to the second pixel circuit 130b1, the third via-hole 161 may penetrate from the third optoelectronic element 120c1 of the first unit pixel UP-1 to the third pixel circuit 130c1, the fourth via-hole 171 may penetrate from the fourth optoelectronic element 120a2 of the second unit pixel UP-1 to the fourth pixel circuit 130a2, the fifth via-hole 181 may penetrate from the fifth optoelectronic element 120b2 of the second unit pixel UP-2 to the fifth pixel circuit 130b2, the sixth via-hole 191 may penetrate from the sixth optoelectronic element 120c2 of the second unit pixel UP-2 to the sixth pixel circuit 130c2, and the first to sixth via-holes 141, 151, 161, 171, 181, and 191 may each be filled with a conductor.

As an example, areas of the first to sixth pixel circuits 130a1, 130b1, 130c1, 130a2, 130b2, and 130c2 may be larger than the areas of the corresponding first to sixth optoelectronic elements 120a1, 120b1, 120c1, 120a2, 120b2, 120c2, respectively. For example, each area of the first to sixth pixel circuit 130a1, 130b1, 130c1, 130a2, 130b2, and 130c2 may overlap with about 50% to about 100% of the total area of the first to sixth optoelectronic elements 120a1, 120b1, 120c1, 120a2, 120b2, and 120c2, or may overlap with about 60% to about 99%, about 65% to about 98%, about 70% to about 95%, about 75% to about 95% or about 80% to about 95% of the total area of the first to sixth optoelectronic elements 120a1, 120b1, 120c1, 120a2, 120b2, and 120c2, within the range in the plan view.

As above-described, as the first to sixth pixel circuits 130a1, 130b1, 130c1, 130a2, 130b2, and 130c2 are stacked in the thickness direction (e.g., the z direction) of the substrate 110, the area of each pixel circuit that may be used may be further expanded without being not limited to the sizes of the sub-pixels PX1, PX2, and PX3. Accordingly, regardless of the size of the sub-pixels PX1, PX2, and PX3, the sufficient area for each pixel circuit 130a1, 130b1, 130c1, 130a2, 130b2, and 130c2 may be secured, thereby further improving the performance and stability of the pixel circuits 130a1, 130b1, 130c1, 130a2, 130b2, and 130c2.

FIG. 11 and FIG. 12 show examples in which one unit pixel circuit UPC is stacked with the first and second unit pixels UP-1 and UP-2, but it is not limited thereto, one unit pixel circuit UPC may be stacked with three or more unit pixels UP, for example, by stacking the unit pixel circuit UPC with the unit pixels UP arranged adjacently along N rows and/or M columns, and the area of the unit pixel circuit UPC may be additionally secured up to (N×M) times of each area of the unit pixels UP in another embodiment. At this time, the number of layers of the pixel circuit forming the unit pixel circuit UPC may vary depending on the number S of the sub-pixels PX in the unit pixel UP, and may be additionally secured up to for example (S×N×M) times of areas for the unit pixel circuit UPC with respect to the unit area of each unit pixel UP.

In FIG. 11 and FIG. 12, as an example, although the pixel arrangement shown in FIG. 1 is shown, it is not limited to this, and may be applied equally to the pixel array shown in FIG. 7 or to various other pixel arrays.

While this disclosure has been described in connection with what is presently considered to be practical example embodiments, it is to be understood that the disclosure is not limited to the disclosed embodiments. On the contrary, it is intended to cover various modifications and equivalent arrangements included within the spirit and scope of the appended claims.

What is claimed is:

1. A panel for an electronic device comprising:
a substrate,
a plurality of unit pixels arranged repeatedly along a direction parallel to a major surface of the substrate, and
a plurality of unit pixel circuits including a unit pixel circuit that is repeatedly arranged along the direction parallel to the major surface of the substrate and electrically connected to a corresponding unit pixel among the plurality of unit pixels,
wherein each unit pixel includes:
a red sub-pixel including a red optoelectronic element configured to display red color or detect light in a red wavelength spectrum,
a green sub-pixel including a green optoelectronic element configured to display green color or detect light in a green wavelength spectrum, and
a blue sub-pixel including a blue optoelectronic element configured to display blue color or detect light in a blue wavelength spectrum,
wherein each unit pixel circuit includes:
a red pixel circuit electrically connected to the red optoelectronic element,
a green pixel circuit electrically connected to the green optoelectronic element, and
a blue pixel circuit electrically connected to the blue optoelectronic element, and
wherein the red pixel circuit, the green pixel circuit, and the blue pixel circuit are stacked each other along a thickness direction of the substrate.

2. The panel for the electronic device of claim 1, wherein
the red optoelectronic element, the green optoelectronic element, and the blue optoelectronic element are arranged side by side along the direction parallel to the major surface of the substrate,
the red pixel circuit overlaps with the red optoelectronic element along the thickness direction of the substrate and additionally overlaps with at least one of the green optoelectronic element or the blue optoelectronic element,
the green pixel circuit overlaps with the green optoelectronic element along the thickness direction of the substrate and additionally overlaps with at least one of the red optoelectronic element or the blue optoelectronic element, and
the blue pixel circuit overlaps with the blue optoelectronic element along the thickness direction of the substrate and additionally overlaps with at least one of the red optoelectronic element or the green optoelectronic element.

3. The panel for the electronic device of claim 2, wherein
the red pixel circuit overlaps about 50% to about 100% of a total area of the red optoelectronic element, the green optoelectronic element, and the blue optoelectronic element,
the green pixel circuit overlaps about 50% to about 100% of the total area of the red optoelectronic element, the green optoelectronic element, and the blue optoelectronic element, and
the blue pixel circuit overlaps about 50% to about 100% of the total area of the red optoelectronic element, the green optoelectronic element, and the blue optoelectronic element.

4. The panel for the electronic device of claim 1, wherein each active layer of the red pixel circuit, the green pixel circuit, and the blue pixel circuit includes a two-dimensional material, oxide, silicon, an organic material, or a combination thereof.

5. The panel for the electronic device of claim 4, wherein each active layer of the red pixel circuit, the green pixel circuit, and the blue pixel circuit includes a monocrystalline or a monocrystalline-like two-dimensional material configured to be grown or deposited at temperatures from about 25° C. to about 400° C.

6. The panel for the electronic device of claim 4, wherein the two-dimensional material includes a two-dimensional inorganic compound, graphene, borophene, germanene, stanene, phosphorene, bismuthene, tellurene, metal chalcogenide, boron nitride, black phosphorus, a two-dimensional organic compound, a two-dimensional organic/inorganic compound or combinations thereof.

7. The panel for the electronic device of claim 4, wherein each active layer of the red pixel circuit, the green pixel circuit, and the blue pixel circuit includes 1 to 10 monolayers made of the two-dimensional material.

8. The panel for the electronic device of claim 1, wherein each thickness of the red pixel circuit, the green pixel circuit, and the blue pixel circuit is about 0.1 nanometers (nm) to about 3 micrometers (μm).

9. The panel for the electronic device of claim 1, wherein
the red pixel circuit, the green pixel circuit, and the blue pixel circuit are separated by an insulation layer, and
each of the red pixel circuit, the green pixel circuit, and the blue pixel circuit is electrically connected to corresponding one of the red optoelectronic element, the green optoelectronic element, the blue optoelectronic element through a conductive material filled in a via-hole in the insulation layer.

10. The panel for the electronic device of claim 1, wherein
the plurality of unit pixel circuits includes a first unit pixel circuit and a second unit pixel circuit adjacent to each other in the thickness direction of the substrate, and
the red pixel circuit, the green pixel circuit, and the blue pixel circuit included in the first unit pixel circuit, and the red pixel circuit, the green pixel circuit, and the blue pixel circuit included in the second unit pixel circuit are stacked each other along the thickness direction of the substrate.

11. The panel for the electronic device of claim 10, wherein
the plurality of unit pixels includes a first unit pixel and a second unit pixel adjacent to each other,
the red optoelectronic element, the green optoelectronic element, and the blue optoelectronic element included the first unit pixel, and the red optoelectronic element, the green optoelectronic element, and the blue optoelectronic element included in the second unit pixel are arranged side by side along the direction parallel to the major surface of the substrate,
the red pixel circuit of the first unit pixel circuit overlaps with about 50% to about 100% of a total area of the red optoelectronic element, the green optoelectronic element, and the blue optoelectronic element included the first unit pixel, and the red optoelectronic element, the green optoelectronic element, and the blue optoelectronic element included in the second unit pixel,
the green pixel circuit of the first unit pixel circuit overlaps with about 50% to about 100% of the total area of the red optoelectronic element, the green optoelectronic element, and the blue optoelectronic element included the first unit pixel, and the red optoelectronic element, the green optoelectronic element, and the blue optoelectronic element included in the second unit pixel, and
the blue pixel circuit of the first unit pixel circuit overlaps with about 50% to about 100% of the total area of the red optoelectronic element, the green optoelectronic element, and the blue optoelectronic element included the first unit pixel, and the red optoelectronic element, the green optoelectronic element, and the blue optoelectronic element included in the second unit pixel.

12. The panel for the electronic device of claim 1, wherein
each of the red optoelectronic element, the green optoelectronic element, the blue optoelectronic element is a light emitting diode or a photoelectric conversion diode, and
each of the red pixel circuit, the green pixel circuit, and the blue pixel circuit includes a switching thin film transistor, a driving thin film transistor, a capacitor, or a combination thereof.

13. The panel for the electronic device of claim 1, further comprising a control circuit electrically connected to the plurality of unit pixel circuits,
wherein the control circuit includes a driver integrated circuit, and
wherein the control circuit overlaps with the plurality of unit pixels and the plurality of unit pixel circuits along the thickness direction of the substrate.

14. The panel for the electronic device of claim 13, wherein the control circuit includes a complementary metal-oxide-semiconductor (CMOS) circuit including a two-dimensional material.

15. A panel for an electronic device comprising:
a substrate,
first, second and third optoelectronic elements positioned on the substrate, and configured to emit or absorb lights in a red wavelength spectrum, a green wavelength spectrum and a blue wavelength spectrum, respectively,
a first insulation layer positioned on the first, second, and third optoelectronic elements,
a first pixel circuit positioned on the first insulation layer, and configured to control and drive the first optoelectronic element,
a second insulation layer positioned on the first pixel circuit,
a second pixel circuit positioned on the second insulation layer, and configured to control and drive the second optoelectronic element,
a third insulation layer positioned on the second pixel circuit, and
a third pixel circuit positioned on the third insulation layer, and configured to control and drive the third optoelectronic element,
wherein the first pixel circuit overlaps with the first optoelectronic element along a thickness direction of the substrate and additionally overlaps with at least one of the second optoelectronic element or the third optoelectronic element,
the second pixel circuit overlaps with the second optoelectronic element along the thickness direction of the substrate and additionally overlaps with at least one of the first optoelectronic element or the third optoelectronic element, and
the third pixel circuit overlaps with the third optoelectronic element along the thickness direction of the substrate and additionally overlaps with at least one of the first optoelectronic element or the second optoelectronic element.

16. The panel for the electronic device of claim 15, wherein
the first pixel circuit overlaps about 50% to about 100% of a total area of the first optoelectronic element, the second optoelectronic element, and the third optoelectronic element,
the second pixel circuit overlaps about 50% to about 100% of the total area of the first optoelectronic element, the second optoelectronic element, and the third optoelectronic element, and
the third pixel circuit overlaps about 50% to about 100% of the total area of the first optoelectronic element, the second optoelectronic element, and the third optoelectronic element.

17. The panel for the electronic device of claim 15, wherein
active layers of the first, second, and third pixel circuit include two-dimensional material, and
a thickness of each of the first, second and third pixel circuits is about 0.1 nm to about 3 μm.

18. The panel for the electronic device of claim 15, further comprising:
fourth, fifth and sixth optoelectronic elements positioned adjacent to the first, second and third optoelectronic elements along the direction parallel to a major surface of the substrate, and configured to emit or absorb lights in the red wavelength spectrum, green wavelength spectrum, or blue wavelength spectrum, respectively,
a fourth insulation layer positioned on the third pixel circuit,
a fourth pixel circuit positioned on the fourth insulation layer, and configured to control and drive the fourth optoelectronic element,
a fifth insulation layer positioned on the fourth pixel circuit,
a fifth pixel circuit positioned on the fifth insulation layer, and configured to control and drive the fifth optoelectronic element,
a sixth insulation layer positioned on the fifth pixel circuit, and
a sixth pixel circuit positioned on the sixth insulation layer, and configured to control and drive the sixth optoelectronic element,
wherein the first pixel circuit, the second pixel circuit, and the third pixel circuit each further overlap with at least one of the fourth optoelectronic element, the fifth optoelectronic element or the sixth optoelectronic element along the thickness direction of the substrate,
the fourth pixel circuit overlaps with the fourth optoelectronic element along the thickness direction of the substrate and additionally overlaps with at least one of the first optoelectronic element, the second optoelectronic element, the third optoelectronic element, the fifth optoelectronic element, or the sixth optoelectronic element,
the fifth pixel circuit overlaps with the fifth optoelectronic element along the thickness direction of the substrate and additionally overlaps with at least one of the first optoelectronic element, the second optoelectronic element, the third optoelectronic element, the fourth optoelectronic element, or the sixth optoelectronic element, and
the sixth pixel circuit overlaps with the sixth optoelectronic element along the thickness direction of the substrate and additionally overlaps with at least one of the first optoelectronic element, the second optoelectronic element, the third optoelectronic element, the fourth optoelectronic element, or the fifth optoelectronic element.

19. The panel for the electronic device of claim 15, further comprising:
a control circuit electrically connected to the first, second, and third pixel circuits and including a driver integrated circuit, and
the control circuit overlaps with the first, second, and third optoelectronic elements and the first, second, and third pixel circuits along the thickness direction of the substrate.

20. An electronic device including the panel for the electronic device of claim 1.
